(19) United States
(12) Patent Application Publication
(10) Pub. No.: US 2011/0056429 A1
(43) Pub. Date: Mar. 10, 2011

(54) Rapid Growth Method and Structures for Gallium and Nitrogen Containing Ultra-Thin Epitaxial Structures for Devices

(75) Inventors: James Raring, Goleta, CA (US); Arpan Chakraborty, Goleta, CA (US); Christiane Poblenz, Goleta, CA (US)

(73) Assignee: Soraa, Inc., Goleta, CA (US)

(21) Appl. No.: 12/859,153

(22) Filed: Aug. 18, 2010

Related U.S. Application Data
(60) Provisional application No. 61/235,989, filed on Aug. 21, 2009.
(60) Provisional application No. 61/246,443, filed on Sep. 28, 2009.

(51) Int. Cl. C30B 25/20; C30B 25/02; C30B 25/08

(52) U.S. Cl. 117/101; 117/104

(57) ABSTRACT

A method for rapid growth of gallium and nitrogen containing material is described. The method includes providing a bulk gallium and nitrogen containing substrate. A first epitaxial material of first thickness is formed over the substrate, preferably with a pseudomorphical process. The method also forms a second epitaxial layer over the first to create a stacked structure. The stacked structure consists of a total thickness of less than about 2 microns.

### CROSS-REFERENCE TO RELATED APPLICATIONS

This application claims priority to U.S. Provisional Application No. 61/235,989 (Attorney Docket No. 027364-007500US), filed Aug. 21, 2009, commonly assigned, and hereby incorporated by reference in its entirety for all purposes.

### BACKGROUND OF THE INVENTION

This invention relates generally to lighting techniques. More specifically, embodiments of the invention include techniques for rapid growth of epitaxial structures using Metal-Organic Chemical Vapor Deposition (“MOCVD”) technology on bulk gallium and nitrogen containing materials. The invention can be applied to applications such as white lighting, multi-colored lighting, lighting for flat panel displays and other optoelectronic devices, as well as other uses.

In the late 1800's, Thomas Edison invented the light bulb. The conventional light bulb, commonly called the “Edison bulb,” has been used for over one hundred years. The conventional light bulb uses a tungsten filament enclosed in a glass bulb sealed in a base, which is screwed into a socket. The socket is coupled to AC power or DC power. The conventional light bulb can be found commonly houses, buildings, and outdoor lightings, and other areas requiring light. Unfortunately, drawbacks exist with the conventional Edison light bulb. That is, the conventional light bulb dissipates much thermal energy. More than 90% of the energy used for the conventional light bulb dissipates as thermal energy. Additionally, the conventional light bulb routinely fails often due to thermal expansion and contraction of the filament element.

Fluorescent lighting overcomes some of the drawbacks of the conventional light bulb. Fluorescent lighting uses a tube structure filled with a halogen gas. A pair of electrodes in the tube are connected to an alternating power source through a ballast. When the gas is excited, it discharges, emitting light. Often the tube is coated with phosphor materials. Many buildings use fluorescent lighting, and more recently, fluorescent lighting has been adapted to bases which screw into a standard incandescent bulb socket.

Solid state lighting techniques are also known. Solid state lighting typically relies upon semiconductor materials to produce light emitting diodes (LEDs). At first, red LEDs were demonstrated and introduced into commerce. Red LEDs use Aluminum Indium Gallium Phosphide (AlInGaP) semiconductor materials. More recently, Shuji Nakamura pioneered the use of InGaN materials to produce LEDs emitting light in the blue color spectrum. The blue LEDs led to innovations such as the BlueRay DVD player, solid state white lighting, and other developments. Other colored LEDs have also been proposed, although limitations still exist with solid state lighting. Further details of such limitations are described throughout the present specification and more particularly below.

From the above, it is seen that techniques for improving optical devices is highly desired.

### BRIEF SUMMARY OF THE INVENTION

This invention relates generally to lighting techniques. More specifically, embodiments of the invention include techniques for rapid growth of epitaxial structures using Metal-Organic Chemical Vapor Deposition (“MOCVD”) technology on bulk gallium and nitrogen containing materials. The invention can be applied to applications such as white lighting, multi-colored lighting, lighting for flat panel displays and other optoelectronic devices, as well as other uses.

In a specific embodiment, the present invention provides a method for rapid growth of gallium and nitrogen containing material. The method includes providing a bulk gallium and nitrogen containing substrate having a surface region. The method forms a first epitaxial material of first thickness over the surface of the bulk gallium and nitrogen containing substrate. In a preferred embodiment, the first epitaxial material is pseudomorphically formed. The method also forms second epitaxial material over the first epitaxial material to form a stacked structure. In a preferred embodiment, the second epitaxial materials form an active region, e.g., a junction. Preferably, the stacked structure has a total thickness of less than about 2 microns and characterizes at least substantial portion of an epitaxial region of an optical or electrical device. As used herein, the terms “first” and “second do not generally imply any order or sequence. In a specific embodiment, “pseudomorphically” generally means a lattice matched process where the first epitaxial material is latticed matched to the bulk gallium and nitrogen containing substrate. In a preferred embodiment, the epitaxially formed gallium nitride material and bulk gallium and nitrogen containing substrate has an interface that is substantially or completely latticed matched with each other.

In a specific embodiment, the first epitaxial material is less than 1 micron or less than 100 nm. The epitaxial material is less than 1 micron or less than 10 nm thick. The first epitaxial material is characterized by a stacking fault density of 1E4 cm⁻¹ and less and may have threading dislocations of 1E8 cm⁻² and less. The epitaxial material is characterized by a substantially uniform defect density from a first region to a second region. Preferably, the first epitaxial layer and the surface region have an interface substantially free from nucleation layers, e.g., GaN or AlN or AlGaN, or other gallium and nitrogen containing material.

The present method is characterized by a rapid growth time. In a specific embodiment, the total growth time for formation of gallium and nitrogen containing epitaxial material is less than 1 hour, often less than 30 minutes, but can be less than 15 minutes. In a specific embodiment, the method has a chamber time characterized by total growth time and temperature ramping time. The chamber time may be less than 1 hour, but can be less than 30 minutes. In a specific embodiment, the method has a cycle time, including a chamber time and loading and unloading time which is less than 2 hours, but can be less than 1 hour, or even less than 30 minutes. In a specific embodiment, the gallium and nitrogen containing material is characterized by a growth rate of 4 microns per hour or higher, and the n-type gallium and nitrogen containing material is growth rate is 6 microns per hour or higher. In a specific embodiment, p-type gallium and nitrogen containing material is grown at 2 microns per hour or higher. Preferably, the higher growth rate occurs by way of an atmospheric MOCVD reactor, but the pressure can be slightly above or below atmospheric pressure. The temperature of growth ranges from about 950° C. to 1200° C. or greater for n-type gallium and nitrogen containing material (including silicon dopant, for example) or 950° C. to about 1025° C. for p-type gallium and nitrogen containing material (including magnesium dopant, for example). It should be noted that conventional MOCVD reactors include thermocouple temperature devices coupled to the susceptor, which holds the workpiece and/or substrate, although there can be variations.

In another embodiment, the epitaxial material or materials can be formed in a reactor that can handle multiple wafers in an automatic growth sequence such as an autocassettes. In such a configuration, the wafer loading and unloading from the growth chamber to the loadlock can be performed automatically, without interruption or waiting for wafer transfer between the loadlock and the laboratory or production floor. One configuration uses robotic arms to transfer wafers between the loadlock chamber and the reaction chamber. In such a configuration, the wafers are transferred to and from the growth chamber on a susceptor or tray, on which the wafer will be subjected to epitaxial growth. In a preferred embodiment, the susceptor or tray will contain multiple wafers such that epitaxial material or materials can be formed in a reactor chamber and be grown on multiple wafers at the same time. As used herein, the term auto-cassette generally means a cassette having a sequence of trays, each of which has a substrate wafer or work-piece, that allow for automatic loading of each work piece in a sequential manner. In a preferred embodiment, the cassette including multiple substrates or work-pieces is maintained in a chamber, which couples to the MOCVD chamber, and therefore reduces handling time and the like.

The invention enables a method and system using a multi-wafer auto-cassette and fast growth, e.g., ultra-fast growth. In a specific embodiment, the method and system may be configured for atmospheric pressure growth since it enables faster growth rates and hence shorter growth times, which are desirable. In a specific embodiment, the present system and method may be configured for large substrates, such as 4 inch, 6 inch, and larger, using multi-wafer cassettes. In a preferred embodiment, the method also causes impurities to migrate away from a growth interface. The invention can also be used with a variety of optical devices having emissions ranging from blue, violet, green, yellow, and others. Of course, there can be other variations, modifications, and alternatives.

The present invention provides a method for rapid growth of gallium and nitrogen containing material. The method includes providing a bulk gallium and nitrogen containing substrate having a surface region and forming a first epitaxial material having a first thickness at a growth rate of at least 4 nm per hour overlying the surface region of the bulk gallium and nitrogen containing substrate. The first epitaxial material is pseudomorphically formed overlying the surface region of the bulk gallium and nitrogen containing substrate. The method includes forming one or more second epitaxial materials overlying the first epitaxial material and configured to form a stacked structure.

In yet other embodiments, the epitaxial material or materials can be formed in a single or multiple chambers. In a specific embodiment, one or more or all of the epitaxial materials can be formed in a single chamber and/or multiple chambers, or any combination. In a preferred embodiment, the epitaxial material or materials are formed having a uniform temperature distribution therein. Of course, there can be other variations, modifications, and alternatives.

The method provides smooth epitaxial material. Using for example, n-type gallium and nitrogen containing material, surface roughness is characterized by about 1 nm RMS and less for a five micron by five micron spatial area. Using for example p-type gallium and nitrogen containing material, surface roughness is characterized by about 1 nm RMS and less for a five micron by five micron spatial area.

A further understanding of the nature and advantages of the present invention may be realized by reference to the latter portions of the specification and attached drawings.

### BRIEF DESCRIPTION OF THE DRAWINGS

FIG. 1 is a simplified diagram of a conventional optical device using thick epitaxial layers according to an embodiment of the present invention.

FIG. 2 is a simplified diagram of an optical device according to an embodiment of the present invention.

FIG. 3 is a simplified illustration of a processing method according to an embodiment of the present invention.

FIG. 4 is a simplified plot of temperature against growth time for an optical device processing method according to an embodiment of the present invention.

FIG. 5 is a simplified plot comparing conventional optical devices on sapphire against optical devices according to embodiments of the present invention.

FIG. 6 is a simplified illustration of a growth method for an optical device according to an embodiment of the present invention.

FIG. 7 is a simplified illustration of a growth method for a rectifying p-n junction diode according to an embodiment of the present invention.

FIG. 8 is a simplified illustration of a growth method for a high electron mobility transistor or a metal-semiconductor field effect transistor according to an embodiment of the present invention.

### DETAILED DESCRIPTION OF THE INVENTION

We have observed that conventional GaN-based light emitting diodes (LED) emitting in the ultraviolet and visible regions are based on hetereoepitaxial growth where growth is initiated on a substrate other than GaN such as sapphire, silicon carbide, or silicon. This is due to the limited supply and high cost of free-standing GaN substrates, which has prevented their viability for use in LED manufacture. However, the field of bulk-GaN technology has seen rapid gains over the past couple of years providing promise for large scale deployment into LED manufacture. Such a technology shift will provide benefits to LED performance and manufacturing.

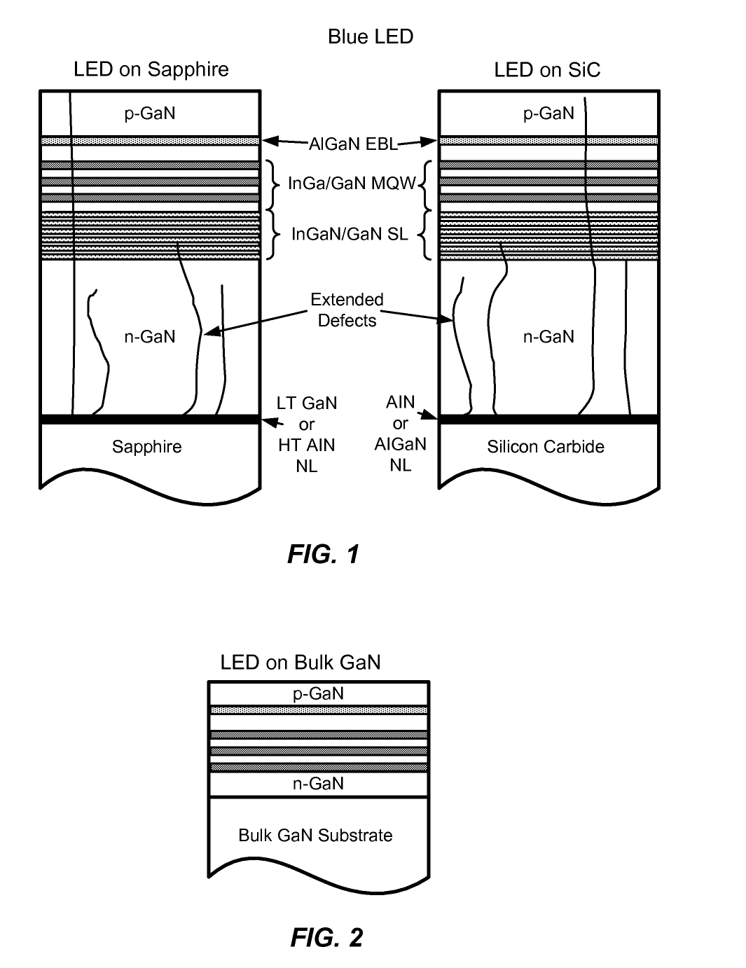

Referring to FIG. 1, growth on foreign substrates often requires low temperature or high temperature nucleation layers at the substrate interface, techniques such as lateral epitaxial overgrowth to mitigate the misfit defects formed at the GaN/substrate interface, a thick buffer layer usually consisting of n-type GaN, but could be others such as InₓAl_{y}Ga_{1-x-y}N, grown between the substrate and light emitting active layers to reduce adverse effects of the misfit defects, InGaN/GaN or AlGaN/GaN or AlInGaN/AlInGaN superlattices placed between the substrate and light emitting active layers to improve the radiative efficiency through strain mitigation, defect mitigation, or some other mechanism, InGaN or AlGaN buffer layers placed between the substrate and light emitting active layers to improve the radiative efficiency through strain mitigation, defect mitigation, or some other mechanism, and thicker p-type GaN layers to mitigate electrostatic discharge (ESD) and reduce leakage current. With the inclusion of all of these layers, conventional LED growth can take from 4 to 10 hours.

By growing LEDs on bulk GaN substrates the low temperature nucleation layer can be eliminated, as shown in FIG. 2, for example. This diagram is merely an illustration and should not unduly limit the scope of the claims herein. One of ordinary skill in the art would recognize other variations, modifications, and alternatives. Defect mitigation techniques such as lateral epitaxial overgrowth are not necessary since there are no misfit dislocation. There is often no need to employ alloyed superlattices or alloy layers between the substrate and the active region to improve radiative efficiency. The buffer layer separating the substrate from the emitting layers can be made ultra thin from 1-2 microns all the way down to 10-20 nm or complete elimination, With all of these relaxed restrictions on layer thicknesses and layer inclusion requirements, the total epitaxial stack thickness can be reduced down to fractions of conventional LED structures. The total LED thickness can be reduced to below 250 nm and theoretically all the way down to ˜30 nm. As a result, the total LED growth time can be reduced down to under 1 hour and theoretically all the way down to ˜15 minutes.

Furthermore, since the many various growth layers required in conventional LEDs grown on foreign substrates often necessitate different growth temperatures the reduced number of growth layers in the LED structure will also require less temperature ramping in the growth recipe. As the total growth time is reduced, the fraction of temperature ramp time within the total cycle time becomes more significant. Therefore the reduced ramping required in this scheme is critical to high growth throughput.

As the desired chamber time is drastically reduced for the wafers, the wafer handling time required to load and unload the wafers from the growth tool become increasingly significant as one tries to reduce total growth cycle time. That is, if there is a 15-30 minute load and unload time at the beginning and end of each growth run, the total time associated with these steps would be 30-60 minutes. With a required chamber time of less than 1 hour, the loading and unloading steps would comprise 1/3 to 1/2 of the total cycle time. A significant portion of the load and unload time is made up from pumping and backfilling a load between the growth chamber and outside environment. The purpose of this is to prevent contaminants from making their way into the growth chamber and to prevent the growth products from leaving the chamber. Configuring the growth tool to auto-transfer wafers to and from the growth chamber to a load-lock chamber equipped with a wafer cassette to store wafers for subsequent growth would offer two fold reduction in total growth cycle time. First, less pump and purge cycles would be required since the loadlock would only need to be pumped and purged once for loading and unloading the entire cassette. That is, if the cassette can hold 10 wafers for consecutive growth, there would only be a total of one pump and purge for the load and the unload cycles for all 10 wafers instead of for each wafer individually. Thus the total pump purge time would be reduced by a factor of 10. The second source of time reduction would be the hot wafer handling enabled by the auto load and unload mechanism. This is due to the fact that transfer mechanisms constructed from metals or other materials can withstand high temperatures and since the wafers would not be subjected to the ambient environment when hot so there would be no likelihood of contamination. These and other features of the present method and structure can be found throughout the present specification and more particularly below.

Finally, this ultra-fast growth method can combined with the auto-cassette feature described above and the use of a multi-wafer MOCVD reactor where 2 or more substrates are loaded into the same the chamber. In another modification, by configuring the reactor with multi chamber, where each chamber is maintained at a different temperature, the temperature cycle time and stabilization time can be minimized. Such a configuration would employ transfer arm to move the wafer from one chamber to the other.

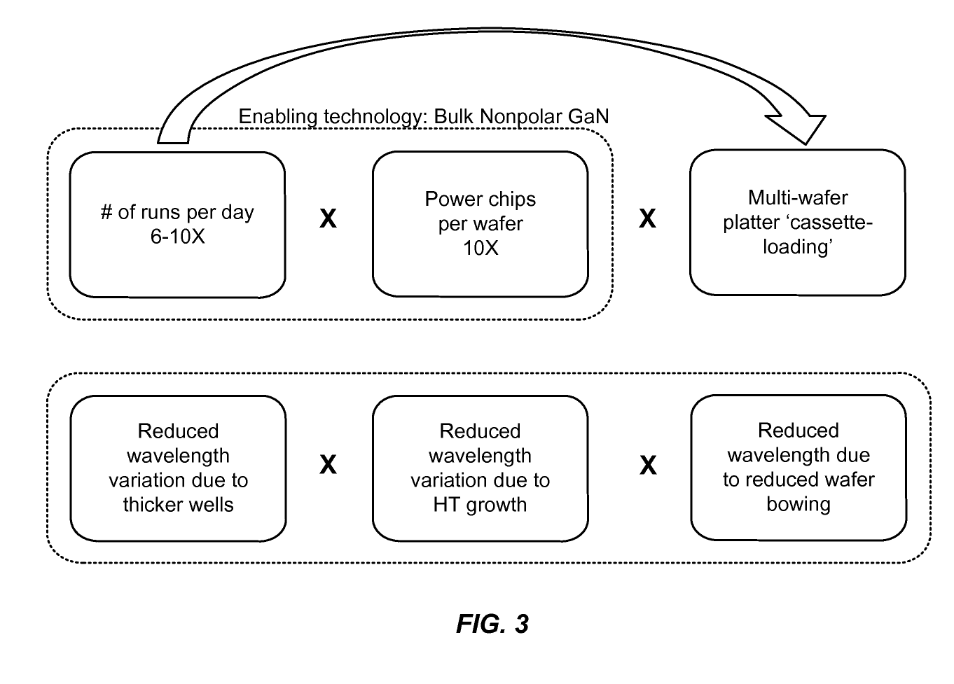

FIG. 3 is a simplified illustration of a processing method according to an embodiment of the present invention. This diagram is merely an illustration and should not unduly limit the scope of the claims herein. One of ordinary skill in the art would recognize other variations, modifications, and alternatives.

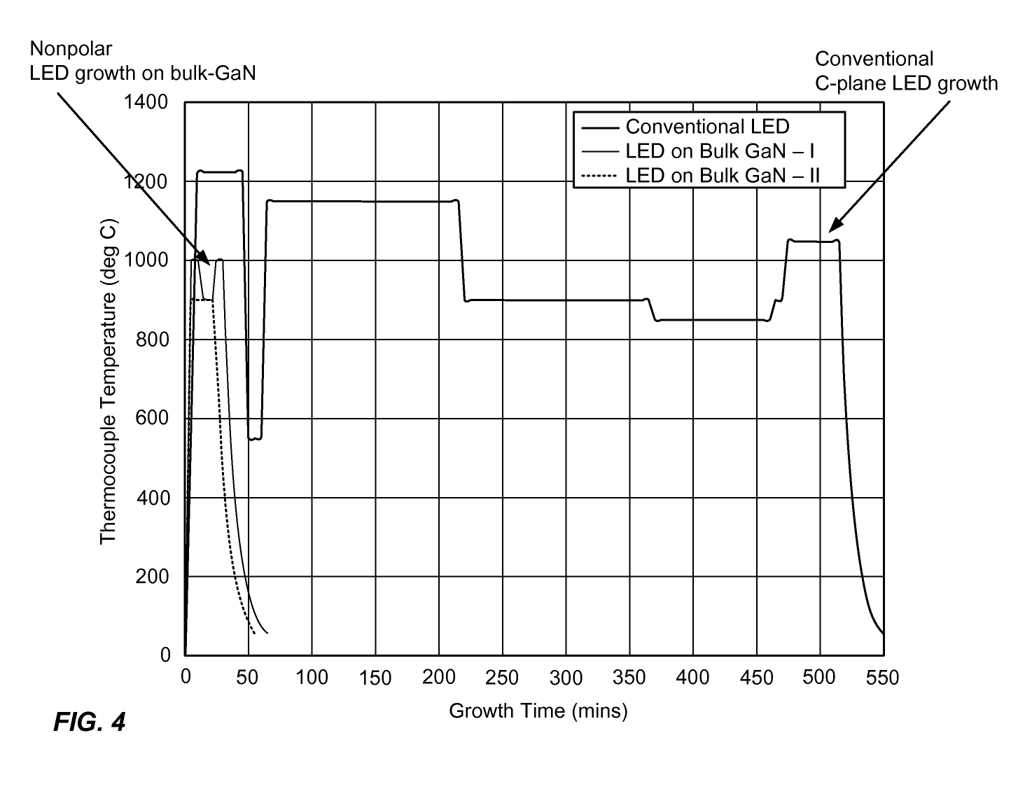

FIG. 4 is a simplified plot of temperature against growth time for an optical device processing method according to an embodiment of the present invention. This diagram is merely an illustration and should not unduly limit the scope of the claims herein. One of ordinary skill in the art would recognize other variations, modifications, and alternatives. As shown, the vertical axis represents thermocouple temperature in Degrees Celsius, while the horizontal axis represents growth time in minutes. As shown, plot represented by 1′, 2′, 3′ illustrates non-polar LED growth on bulk gallium nitride containing material. The bulk gallium nitride material is non-polar GaN, but can be others. As also shown, plot represented by 1, 2, 3, 4, 5, 6, 7, illustrates conventional c-plane LED device growth on sapphire material. The table compares the growth time for the growth of a conventional LED structure on foreign substrate and growth on bulk substrate. Reference to 1 is a LED structure grown on bulk-GaN but employing temperature cycling for the active region growth. Reference to 2 is a LED structure grown on bulk GaN with no temperature cycling, i.e., all the epi-layers are grown at the same temperature. Clearly, the growth time for the bulk gallium nitride material is significantly less than the growth time for the conventional c-plane LED device. Significant reduction in growth time was achieved by eliminating growth layers like the nucleation layer, the InGaN/GaN superlattice, and by reducing the thickness of the n- and p-GaN cladding layers. Of course, there can be other variations modifications, and alternatives.

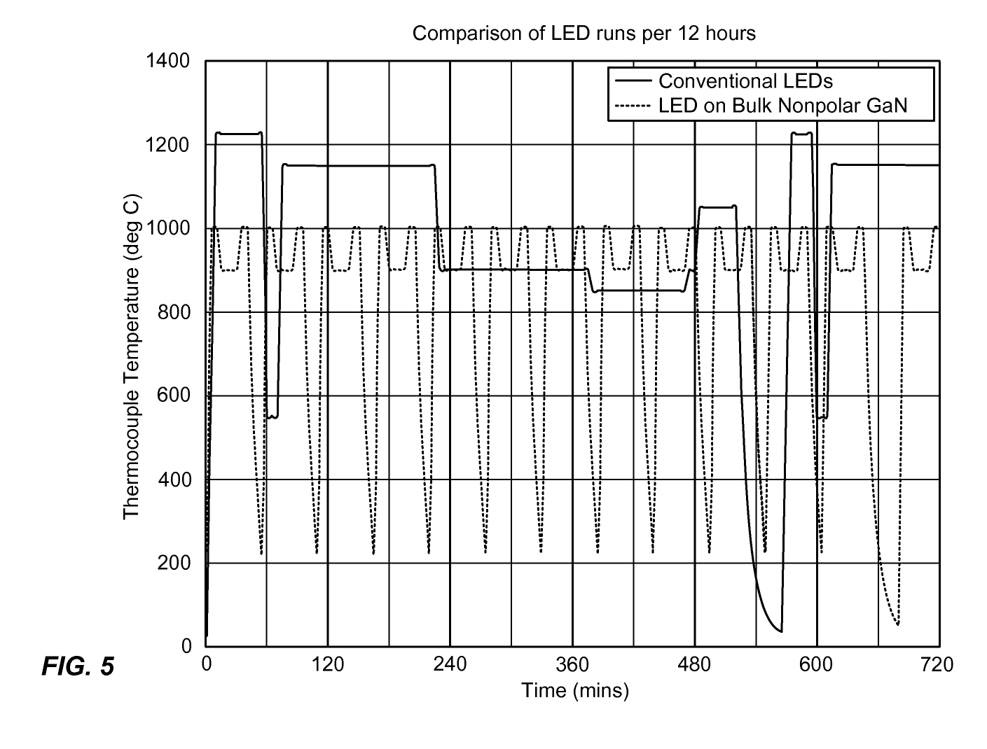

FIG. 5 is a simplified plot comparing conventional optical devices on sapphire against optical devices according to embodiments of the present invention. This diagram is merely an illustration and should not unduly limit the scope of the claims herein. One of ordinary skill in the art would recognize other variations, modifications, and alternatives.

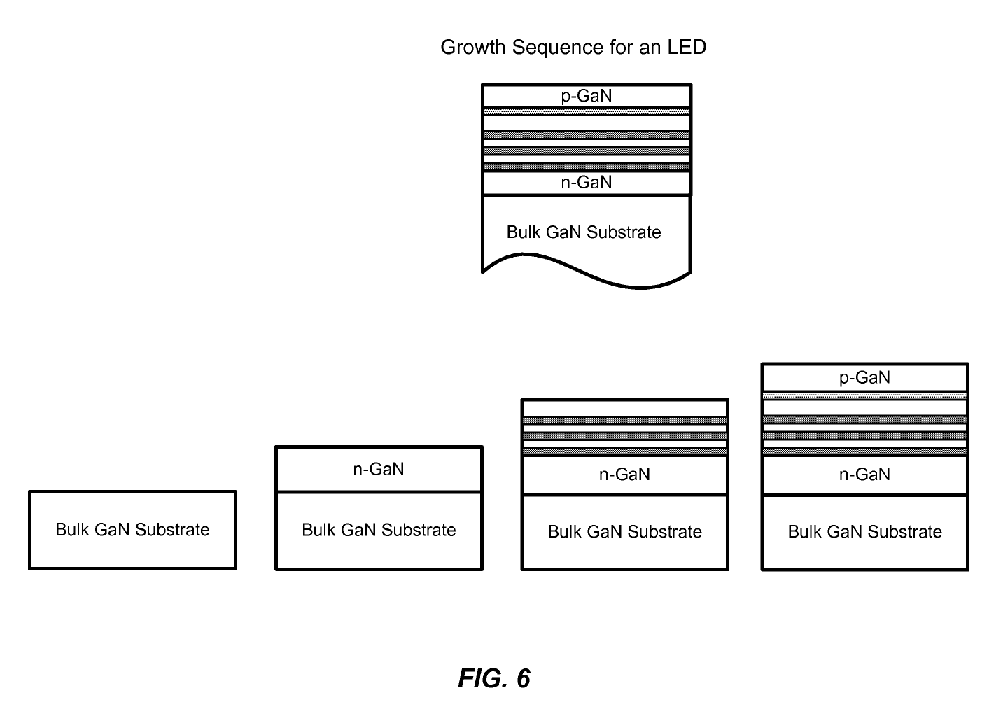

FIG. 6 is a simplified illustration of a growth method for an optical device according to an embodiment of the present invention. This diagram is merely an illustration and should not unduly limit the scope of the claims herein. One of ordinary skill in the art would recognize other variations, modifications, and alternatives. As shown, the growth sequence includes at least (1) n-type epitaxial material; (2) active region; (3) electron blocking region; and (4) p-type epitaxial material. Of course, there can be other variations, modifications, and alternatives. Further details of the present method can be found throughout the present specification and more particularly below.

1. Bulk wafer:

Any orientation, e.g., polar, non-polar, semi-polar, c-plane.

(Al,Ga,In)N based material

Threading dislocation (TD) density<1E8 cm-2

Stacking fault (SF) density<1E4 cm-1

Doping>1E17cm-3

2. N type epitaxial material:

Thickness of<2 um, <1 um, <0.5 um, <0.2 um

(Al,Ga,In)N based material

Growth T<1200 C, <1000 C

Unintentionally doped (UID) or doped

3. Active regions:

At least one AlInGaN layer

Multiple Quantum Well (MQW) structure

QWs are>20 A, >50 A, >80 A in thickness

QW and n- and p-layer growth temperature identical, or similar

Emission wavelength<575 nm, <500 nm, <450 nm, <410 nm

4. P-type epitaxial material

At least one Mg doped layer

Thickness of<0.3 um, <0.1 um

(Al,Ga,In)N based

Growth T<1100 C, <1000 C, <900 C

At least one layer acts as an electron blocking layer

At least one layer acts as a contact layer

Of course, there can be other variations, modifications, and alternatives. Further details are described throughout the present specification and more particularly below.

In a specific embodiment, the present method provides a bulk gallium and nitrogen containing substrate. In a specific embodiment, the gallium nitride substrate member is a bulk GaN substrate characterized by having a semipolar or non-polar crystalline surface region, but can be others. In a specific embodiment, the bulk nitride GaN substrate comprises nitrogen and has a surface dislocation density below 10⁵ cm⁻². The nitride crystal or wafer may comprise AlₓIn_{y}Ga_{1-x-y}N, where 0≦x, y, x+y≦1. In one specific embodiment, the nitride crystal comprises GaN, but can be others. In one or more embodiments, the GaN substrate has threading dislocations, at a concentration between about 10⁵ cm⁻² and about 10⁸ cm⁻², in a direction that is substantially orthogonal or oblique with respect to the surface. As a consequence of the orthogonal or oblique orientation of the dislocations, the surface dislocation density is below about 10⁵ cm⁻². In a preferred embodiment, the present method may include a gallium and nitrogen containing substrate configured with any orientation, e.g., c-plane, a-plane, m-plane. In a specific embodiment, the substrate is preferably (Al,Ga,In)N based. The substrate has a threading dislocation (TD) density<1E8 cm-2, a stacking fault (SF) density<5E3 cm-1, and may be doped with silicon and/or oxygen with a concentration of>1E17cm-3. Of course, there can be other variations, modifications, and alternatives.

As shown, the method forms an n-type material overlying the surface of the gallium and nitrogen containing substrate. In a specific embodiment, the n-type material is formed epitaxially and has a thickness of less than 2 microns, or less than 1 micron, or less than 0.5 micron, or less than 0.2 micron, or can be others. In a specific embodiment, the n-type material is (Al,Ga,In)N based. Growth occurs using a temperature of less than about 1200 Degrees Celsius or less than about 1000 Degrees Celsius, but often is greater than 950 Degrees Celsius. In a preferred embodiment, the n-type material is unintentionally doped (UID) or doped using a silicon species (e.g., Si) or oxygen species (e.g., O2). In a specific embodiment, the dopant may be derived from silane, disilane, oxygen, or the like. In a specific embodiment, the n-type material serves as a contact region of the n-type (silicon-doped) GaN and is characterized by a thickness of about 5 microns and a doping level of about 2×10¹⁸ cm⁻³. In a preferred embodiment, gallium and nitrogen containing epitaxial material is deposited on the substrate by metalorganic chemical vapor deposition (MOCVD) at atmospheric pressure. The ratio of the flow rate of the group V precursor (ammonia) to that of the group III precursor (trimethyl gallium, trimethyl indium, trimethyl aluminum) during growth is between about 3,000 and about 12,000. Of course, there can be other variations, modifications, and alternatives.

In a preferred embodiment, the method forms an active region overlying the n-type contact region. The active region includes at least one AlInGaN layer and preferably includes a multi-quantum well structure. Each of the quantum wells can be characterized by a thickness of 20 Angstroms and less, 50 Angstroms and less, or 80 Angstroms and less, or combinations, and the like. Optionally, the active region may also include a barrier region or regions. In a specific embodiment, growth temperature for the n-type contact region and quantum well regions are the same or slightly different. In a preferred embodiment, the MQW structure is configured for emissions of 500 nm and less, 450 nm and less, or 410 nm and less, or others.

In a specific embodiment, an undoped AlGaN electron blocking region is deposited. In a specific embodiment, the blocking region has a thickness of 0.3 micron and less or 0.1 micron and less. In a preferred embodiment, a p-type GaN contact region is deposited. Preferably, growth temperature of the p-type contact region is 1100 Degrees Celsius and less or 1000 Degrees Celsius and less or 900 Degrees Celsius and less. Indium tin oxide (ITO) is e-beam evaporated onto the p-type contact layer as the p-type contact and rapid-thermal-annealed. LED mesas, with a size of about 300×300 μm², are formed by photolithography and dry etching using a chlorine-based inductively-coupled plasma (ICP) technique. Ti/Al/Ni/Au is e-beam evaporated onto the exposed n-GaN layer to form the n-type contact, Ti/Au is e-beam evaporated onto a portion of the ITO layer to form a p-contact pad, and the wafer is diced into discrete LED dies. Electrical contacts are formed by conventional wire bonding. Of course, there can be other variations, modifications, and alternatives.

In other embodiments, the present method is characterized by a rapid growth time. In a specific embodiment, the total growth time is characterized by formation of gallium and nitrogen containing epitaxial material. The total growth time is less than 1 hour, less than 30 minutes, less than 15 minutes, or others. In a specific embodiment, the method has a chamber time characterized by total growth time and temperature ramping time. The chamber time may be less than 1 hour, less than 30 minutes, or others. In a specific embodiment, the method has a cycle time, which is provided by a chamber time and loading and unloading time. The cycle time may be less than 2 hours, less than 1 hour, less than 30 minutes, or others. In a specific embodiment, the gallium and nitrogen containing material is characterized by a growth rate of 4 microns per hour or higher or n-type gallium and nitrogen containing material is 6 microns per hour or higher. In a specific embodiment, p-type gallium and nitrogen containing material is grown at 2 microns per hour or higher. Preferably, the higher growth rate occurs by way of an atmospheric MOCVD reactor, which may also be slightly above or below atmospheric pressure. The temperature of growth can range from about 950 Degrees Celsius to 1200 Degrees Celsius or greater for n-type gallium and nitrogen containing material (including silicon dopant, for example) or 950 Degrees Celsius to about 1025 Degrees Celsius for p-type gallium and nitrogen containing material (including magnesium dopant, for example). Of course, there can be other variations, modifications, and alternatives.

In a preferred embodiment, the present method provides a smooth resulting epitaxial material. Using for example, n-type gallium and nitrogen containing material, surface roughness is characterized by about 1 nm RMS and less for a five micron by five micron spatial area. In a specific embodiment, using for example p-type gallium and nitrogen containing material, surface roughness is characterized by about 1 nm RMS and less for a five micron by five micron spatial area. Of course, there can be other variations, modifications, and alternatives.

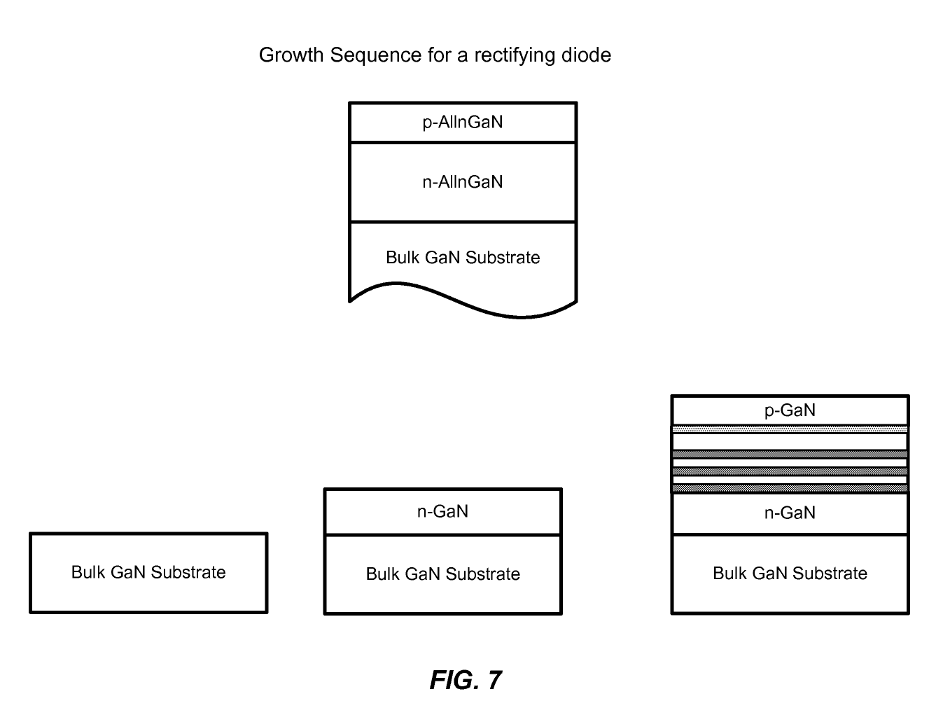

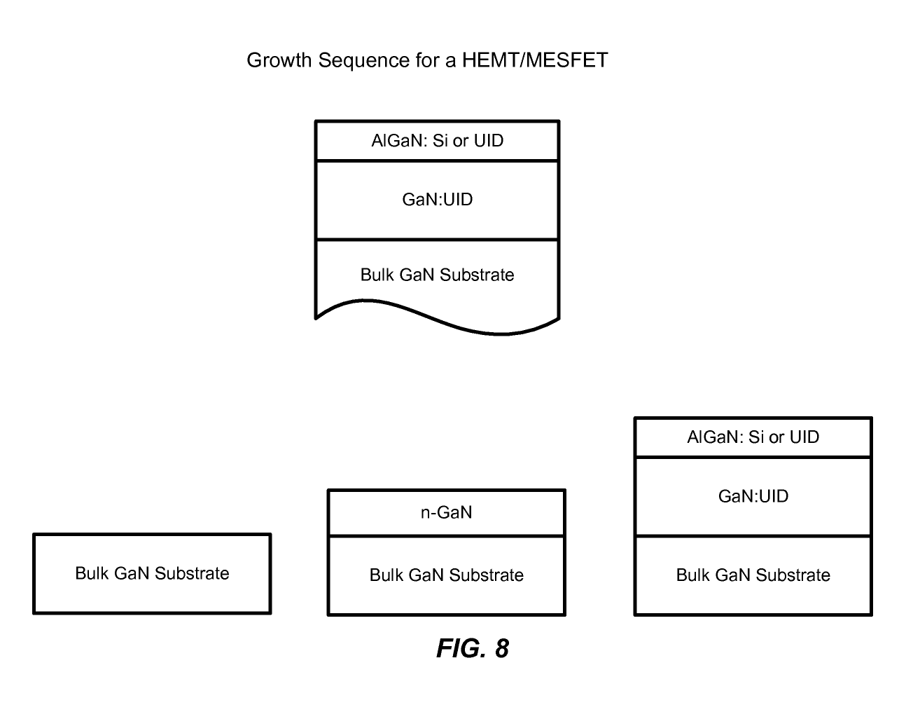

FIG. 7 is a simplified illustration of a growth method for a rectifying p-n junction diode according to an embodiment of the present invention. This diagram is merely an illustration and should not unduly limit the scope of the claims herein. One of ordinary skill in the art would recognize other variations, modifications, and alternatives. As shown, the growth sequence includes at least (1) n-type epitaxial material; and (4) p-type epitaxial material. Of course, there can be other variations, modifications, and alternatives. Further details of the present method can be found throughout the present specification and more particularly below.

1. Bulk wafer

Any orientation

(Al,Ga,In)N based

Threading dislocation (TD) density<1E8 cm-2

Stacking fault (SF) density<5E3 cm-1

Doping>1E17cm-3

2. N type layer

<2 um, <1 um, <0.5 um, <0.2 um

(Al,Ga,In) N based

Growth T<1200 C, <1000 C

UID or doped

3. P-type layer

At least one Mg doped layer

<0.3 um, <0.1 um

(Al,Ga,In)N based

Growth T<1100 C, <1000 C, <900 C

At least one layer acts as an electron blocking layer

At least one layer acts as a contact layer

Of course, there can be other variations, modifications, and alternatives. Further details are described throughout the present specification.

FIG. 8 is a simplified illustration of a growth method for a high electron mobility transistor or a metal-semiconductor field effect transistor according to an embodiment of the present invention. This diagram is merely an illustration and should not unduly limit the scope of the claims herein. One of ordinary skill in the art would recognize other variations, modifications, and alternatives. As shown, the growth sequence includes at least (1) unintentional doped epitaxial material (buffer); and (4) an (AlInGaN) barrier, either unintentional doped or n-type epitaxial material. Of course, there can be other variations, modifications, and alternatives. Further details of the present method can be found throughout the present specification and more particularly below.

1. Bulk wafer

Any orientation

(Al,Ga,In)N based

Threading dislocation (TD) density<1E8 cm-2

Stacking fault (SF) density<5E3 cm-1

Doping>1E17 cm-3

2. Buffer layer

<2 um, <1 um, <0.5 um, <0.2 um

(Al,Ga,In)N based

Growth T<1200 C, <1000 C

UID or doped

At least one layer semi-insulating by Fe or C doping

### 3. Barrier-layer

<0.1 um, <500 nm, <30 nm

(Al,Ga,In)N based

Growth T<1200 C, <1100 C, <1000 C

At least one layer doped with Si

Of course, there can be other variations, modifications, and alternatives. Further details are described throughout the present specification.

In a specific embodiment, the nitride crystal comprises nitrogen and has a surface dislocation density below 10⁵ cm⁻². The nitride crystal or wafer may comprise AlₓIn_{y}Ga_{1-x-y}N, where 0≦x, y, x+y≦1. In one specific embodiment, the nitride crystal comprises GaN. In a preferred embodiment, the nitride crystal is substantially free of low-angle grain boundaries, or tilt boundaries, over a length scale of at least 3 millimeters. The nitride crystal may also include a release layer with an optical absorption coefficient greater than 1000 cm⁻¹ at at least one wavelength where the base crystal underlying the release layer is substantially transparent, with an optical absorption coefficient less than 50 cm⁻¹, and may further comprise a high quality epitaxial layer, which also has a surface dislocation density below 10⁵ cm⁻². The release layer may be etched under conditions where the nitride base crystal and the high quality epitaxial layer are not. Of course, there can be other variations, modifications, and alternatives.

In a specific embodiment, the substrate may have a large-surface orientation within ten degrees, within five degrees, within two degrees, within one degree, within 0.5 degree, or within 0.2 degree of (0 0 0 1), (0 0 0 −1), {1 −1 0 0}, {1 1 −2 0}, {1 -1 0 ±1}, {1 −1 0 ±2}, {1 −1 0 ±3}, or {1 1 −2±2}. The substrate may have a dislocation density below 10⁴ cm⁻², below 10³ cm⁻², or below 10² cm⁻². The nitride base crystal or wafer may have an optical absorption coefficient below 100 cm⁻¹, below 50 cm⁻¹ or below 5 cm⁻¹ at wavelengths between about 465 nm and about 700 nm. The nitride base crystal may have an optical absorption coefficient below 100 cm⁻¹, below 50 cm⁻¹ or below 5 cm⁻¹ at wavelengths between about 700 nm and about 3077 nm and at wavelengths between about 3333 nm and about 6667 nm. Of course, there can be other variations, modifications, and alternatives.

While the above is a full description of the specific embodiments, various modifications, alternative constructions and equivalents may be used. As an example, the invention can be applied to using autocassette MOCVD reactor where the cassette holds two (or ten or more) or more single wafers or wafer platters for multi-wafer reactors. In one or more embodiments, the epitaxial structure can form an LED device capable of emitting electromagnetic radiation in a range of 390-420 nm, 420-460 nm, 460-4500 nm, 500-600 nm, and others. In a specific embodiment, various devices such as a p-n diode, a Schottky diode, a transistor, a high electron mobility transistor (HEMT), a bipolar junction transistor (BJT), a heterojunction bipolar transistor (HBT), a metal-semiconductor field effect transistor (MESFET), a metal-oxide-semiconductor field effect transistor (MOSFET), a metal-insulator-semiconductor heterojunction field effect transistor (MISHFET), combinations, and others. In alternative embodiments, the present method can be applied to laser diode devices such as those described in U.S. Ser. No. 12/759,273 (Attorney Docket No. 027600-000210US), which is hereby incorporated by reference for all purposes. In one or more embodiments, the gallium and nitrogen containing material can be characterized by one or various surface orientations, e.g., nonpolar, semipolar, polar. Further details of the present invention can be found throughout the present specification and more particularly to the example below.

### EXAMPLE

To prove the principle and operation of the experiment, we performed certain experiments. We demonstrated high quality GaN epitaxial films at high growth rates of 4 microns per hour and greater. The experiment was performed using an atmospheric pressure MOCVD reactor configured with reactant gases, as noted. The chamber is configured to provide thermal energy to the growth as noted. The temperature of the reaction is measured by thermo-couples coupled to the susceptor, which holds the bulk wafer. It is believed that the temperature of the growth is slightly lower than those noted herein. Additionally, the experiment was performed using the following parameters.

1. Bulk wafer:

Non-polar, semipolar, or polar

GaN based material

Threading dislocation (TD) density<1E8 cm-2

Stacking fault (SF) density<1E4 cm-1

N-type Silicon Doping>1E17cm-3

2. N type epitaxial material:

Thickness of<2 um

(Al,Ga,In) N based material

950 C<Growth Temperature<1050 C

Silicon doped

Roughness 2 nanometers RMS over 25 microns area

We demonstrated high quality films having a surface roughness of 2 nm RMS and less over 25 microns in area using rapid growth techniques. Of course, there can be other variations, modifications, and alternatives.

While the above is a full description of the specific embodiments, various modifications, alternative constructions and equivalents may be used. As an example, the invention can be applied to using autocassette MOCVD reactor where the cassette holds two (or ten or more) or more single wafers or wafer platters for multi-wafer reactors. In one or more embodiments, the epitaxial structure can form an LED device capable of emitting electromagnetic radiation in a range of 390-420 nm, 420-460 nm, 460-4500 nm, 500-600 nm, and others. In a specific embodiment, various devices such as a p-n diode, a Schottky diode, a transistor, a high electron mobility transistor (HEMT), a bipolar junction transistor (BJT), a heterojunction bipolar transistor (HBT), a metal-semiconductor field effect transistor (MESFET), a metal-oxide-semiconductor field effect transistor (MOSFET), a metal-insulator-semiconductor heterojunction field effect transistor (MISHFET), combinations, and others. In alternative embodiments, the present method can be applied to laser diode devices such as those described in U.S. Ser. No. 12/759,273 (Attorney Docket No. 027600-000210US), which is hereby incorporated by reference for all purposes. In one or more embodiments, the gallium and nitrogen containing material can be characterized by one or various surface orientations, e.g., nonpolar, semipolar, polar. Therefore, the above description and illustrations should not be taken as limiting the scope of the present invention which is defined by the appended claims.

What is claimed is:

1. A method for rapid growth of gallium and nitrogen containing material comprising:
providing a bulk gallium and nitrogen containing substrate having a surface region;
forming a first epitaxial material having a first thickness overlying the surface region of the bulk gallium and nitrogen containing substrate, the first epitaxial material being pseudomorphically formed overlying the surface region of the bulk gallium and nitrogen containing substrate; and
forming one or more second epitaxial materials overlying the first epitaxial material and configured to form a stacked structure;
whereupon the stacked structure consists of a total thickness of less than about 2 microns and characterizes at least substantial portion of an epitaxial region of an optical or electrical device.

2. The method of claim 1 wherein the first epitaxial material is less than 1 micron.

3. The method of claim 1 wherein the first epitaxial material is less than 500 nm.

4. The method of claim 1 wherein the first epitaxial material is less than 100 nm.

5. The method of claim 1 wherein the one or more second epitaxial materials is less than 1 micron.

6. The method of claim 1 wherein the one or more second epitaxial materials is less than about 500 nm.

7. The method of claim 1 wherein the one or more second epitaxial materials is less than about 100 nm.

8. The method of claim 1 wherein the one or more second epitaxial materials is less than about 1000 nm.

9. The method of claim 1 wherein the first epitaxial material is characterized by a stacking fault density of 1E4 cm-1 and less.

10. The method of claim 1 wherein the first epitaxial material is characterized by threading dislocations of 1E8 cm-2 and less or of 1E6 cm-2 and less.

11. The method of claim 1 wherein the first epitaxial material is characterized by a substantially uniform defect density from a first region to a second region.

12. The method of claim 11 wherein the substantially uniform defect density is essentially uniform.

13. The method of claim 11 wherein the substantially uniform defect density is completely uniform.

14. The method of claim 1 wherein the first epitaxial material and the surface region comprises an interface substantially free from one or more nucleation layers.

15. The method of claim 1 wherein the total thickness is less than about 1 micron.

16. The method of claim 1 wherein the total thickness is less than about 500 nm.

17. The method of claim 1 wherein the total thickness is less than about 200 nm.

18. The method of claim 1 wherein the stacked structure is provided within a total growth time characterized by formation of a gallium and nitrogen containing epitaxial material.

19. The method of claim 18 wherein the total growth time is less than 1.5 or less than 2 hours.

20. The method of claim 18 wherein the total growth time is less than 1 hour.

21. The method of claim 18 wherein the total growth time is less than 30 minutes.

22. The method of claim 18 wherein the total growth time is less than 15 minutes.

23. The method of claim 1 wherein the stacked structure is provided within a chamber time characterized by a total growth time and a temperature ramping time.

24. The method of claim 23 wherein the chamber time is less than 1 hour or less than 1.5 hours.

25. The method of claim 23 wherein the chamber time is less than 30 minutes.

26. The method of claim 1 wherein the stacked structure is provided within a cycle time characterized by a chamber time and a loading and unloading time.

27. The method of claim 26 wherein the cycle time is less than 2 hours or less than 2.5 hours.

28. The method of claim 26 wherein the cycle time is less than 1 hour.

29. The method of claim 26 wherein the cycle time is less than 30 minutes.

30. The method of claim 1 wherein the first epitaxial material and the one or more second epitaxial materials is deposited in a single chamber.

31. The method of claim 1 wherein the first epitaxial material and the one or more second epitaxial materials are deposited respectively in multiple chambers.

32. The method of claim 1 further comprising maintaining a determined temperature during formation of the first epitaxial material and the one or more second epitaxial materials.

33. The method of claim 1 further comprising using an autocassette MOCVD reactor, the autocassette MOCVD reactor configured to hold two or more single wafers or wafer platters for multi-wafer reactors.

34. The method of claim 1 further comprising using an autocassette MOCVD reactor, the autocassette MOCVD reactor configured to hold 3 or more single wafers or wafer platters for multi-wafer reactors.

35. The method of claim 1 further comprising using an autocassette MOCVD reactor, the autocassette MOCVD reactor configured to hold ten or more single wafers or wafer platters for multi-wafer reactors.

36. The method of claim 1 wherein the epitaxial stacked structure forms an LED emitting in a wavelength range of 390-420 nm.

37. The method of claim 1 wherein the epitaxial stacked structure forms an LED emitting in a wavelength range of 420-460 nm.

38. The method of claim 1 wherein the epitaxial stacked structure forms an LED emitting in a wavelength range of 460-500 nm.

39. The method of claim 1 wherein the epitaxial stacked structure forms an LED emitting in a wavelength range of 500-600 nm.

40. The method of claim 1 wherein the epitaxial stacked structure forms a p-n diode.

41. The method of claim 1 wherein the epitaxial stacked structure forms a laser diode.

42. The method of claim 1 wherein wherein the epitaxial stacked structure forms a Schottky diode.

43. The method of claim 1 wherein the epitaxial stacked structure forms a transistor.

44. The method of claim 1 wherein the epitaxial stacked structure forms a high electron mobility transistor (HEMT).

45. The method of claim 1 wherein the epitaxial stacked structure forms a bipolar junction transistor (BJT).

46. The method of claim 1 wherein the epitaxial stacked structure forms a heterojunction bipolar transistor (HBT).

47. The method of claim 1 wherein the epitaxial stacked structure forms a metal-semiconductor field effect transistor (MESFET).

48. The method of claim 1 wherein the epitaxial stacked structure forms a metal-oxide-semiconductor field effect transistor (MOSFET).

49. The method of claim 1 wherein the epitaxial stacked structure forms a metal-insulator-semiconductor heterojunction field effect transistor (MISHFET).

50. The method of claim 1 wherein the gallium and nitrogen containing substrate is characterized by a nonpolar surface orientation.

51. The method of claim 1 wherein the gallium and nitrogen containing substrate is characterized by a semipolar surface orientation or a polar surface orientation.

52. A method for rapid growth of gallium and nitrogen containing material comprising:
providing a bulk gallium and nitrogen containing substrate having a surface region;
forming a first epitaxial material having a first thickness at a desired growth rate overlying the surface region of the bulk gallium and nitrogen containing substrate, the first epitaxial material being pseudomorphically formed overlying the surface region of the bulk gallium and nitrogen containing substrate; and
forming one or more second epitaxial materials overlying the first epitaxial material and configured to form a stacked structure.

53. The method of claim 52 wherein the forming is maintained at a temperature ranging from about 950 Degrees Celsius to about 1,200 Degrees Celsius; and wherein the desired growth rate is 4 microns per hour and greater.

54. The method of claim 52 wherein the providing comprising selecting the bulk gallium and nitrogen containing substrate from an auto-cassette maintained in a chamber.

55. The method of claim 52 wherein the forming is provided in an atomospheric pressure MOCVD chamber.

56. The method of claim 52 wherein the gallium and nitrogen containing substate is maintained at about atmospheric pressure during the forming.

57. The method of claim 52 wherein the first thickness of the first epitaxial material is characterized by a surface roughness of less about 2 nm RMS for a five by five micron square.

58. The method of claim 52 wherein the first thickness of first epitaxial material is an n-type material.

59. The method of claim 52 wherein the second epitaxial material is a p-type material.

60. The method of claim 52 wherein the first epitaxial material is characterized by a stacking fault density of 1E4 cm-1 and less.
